(19) United States
(12) Patent Application Publication
(10) Pub. No.: US 2009/0057846 A1
(43) Pub. Date: Mar. 5, 2009

(54) METHOD TO FABRICATE ADJACENT SILICON FINS OF DIFFERING HEIGHTS

(76) Inventors: Brian S. Doyle, Portland, OR (US); Been-Yih Jin, Lake Oswego, OR (US); Uday Shah, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/848,235

(22) Filed: Aug. 30, 2007

(51) Int. Cl. H01L 29/06; H01L 21/20

(52) U.S. Cl. 257/623; 438/492; 257/E29.112; 257/E21.09

(57) ABSTRACT

A method to fabricate adjacent silicon fins of differing heights comprises providing a silicon substrate having an isolation layer deposited thereon, patterning the isolation layer to form first and second isolation structures, patterning the silicon substrate to form a first silicon fin beneath the first isolation structure and a second silicon fin beneath the second isolation structure, depositing an insulating layer on the substrate, planarizing the insulating layer to expose top surfaces of the first and second isolation structures, depositing and patterning a masking layer to mask the first isolation structure but not the second isolation structure, applying a wet etch to remove the second isolation structure and expose the second silicon fin, epitaxially depositing a silicon layer on the second silicon fin, and recessing the insulating layer to expose at least a portion of the first silicon fin and at least a portion of the second silicon fin.

### BACKGROUND

In the manufacture of integrated circuits, semiconductor bodies used in multi-gate transistors, also knows as silicon “fins”, are generally formed with uniform dimensions. To generate more drive current, the number of fins must be increased since there are no fins with intermediate dimensions available. There is currently a need for silicon fins having different dimensions. For instance, the constraints for logic and memory transistors are different—logic transistors require deep fins to maximize the Idsat/layout area while memory transistors require relatively shallow fins. Furthermore, transistor width differences are needed for pass transistor and pull-down in static random access memory (SRAM) devices.

One conventional work-around for producing fins with differing dimensions begins by fabricating uniform silicon fins. As shown in FIG. 1A, an insulating material 104, such as a shallow trench isolation (STI) material, is deposited around uniform fins 102 on a substrate 100. This conventional process then etches the STI material 104 at differing depths to expose differing heights of the silicon fins 102, as shown in FIG. 1B. The height of the STI material 104 therefore varies across the surface of the substrate 100.

The problem with this prior art approach concerns what happens to the polysilicon that is later used to form gate electrodes. After a polysilicon layer is deposited and planarized, the polysilicon must be patterned to form the gate electrodes 106. This requires etching the polysilicon down to the surface of the STI material 104. Since the height of the STI material 104 varies across the substrate, the patterning of some polysilicon gates 106 reaches their endpoint while others are still being etched, as shown in FIG. 1B. The polysilicon gates reaching their endpoint first then suffer from over-etching and notching as the remainder of the polysilicon gates are etched, leading to shorter channel effects for the shorter fins. As such, improved processes are needed to form silicon fins of varying heights.

### BRIEF DESCRIPTION OF THE DRAWINGS

FIGS. 1A and 1B illustrate an issue with prior art methods of forming silicon fins with differing heights.

FIG. 2 is a method of fabricating silicon fins having differing heights in accordance with an implementation of the invention.

FIGS. 3A to 3H illustrate structures formed with the method of FIG. 2 is carried out.

### DETAILED DESCRIPTION

Described herein are systems and methods of fabricating silicon fins of varying height. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide methods of fabricating adjacent silicon fins having different dimensions, such as a relatively long silicon fin adjacent to a relatively short silicon fin. This enables transistors having semiconductor bodies of differing widths to be formed adjacent to one another. The implementations provided herein can form such silicon fins without conventional issues such as the subsequent over-etching or notching of the polysilicon gate electrodes.

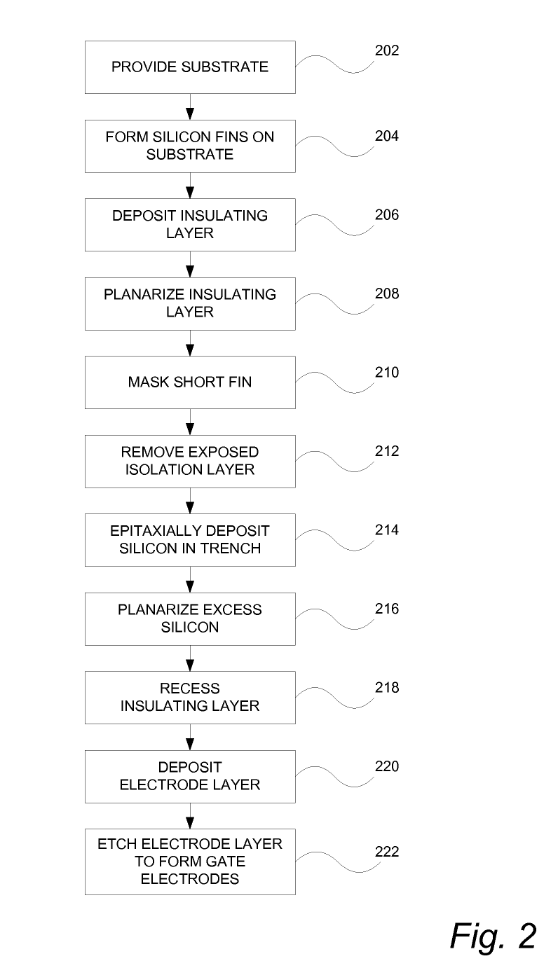

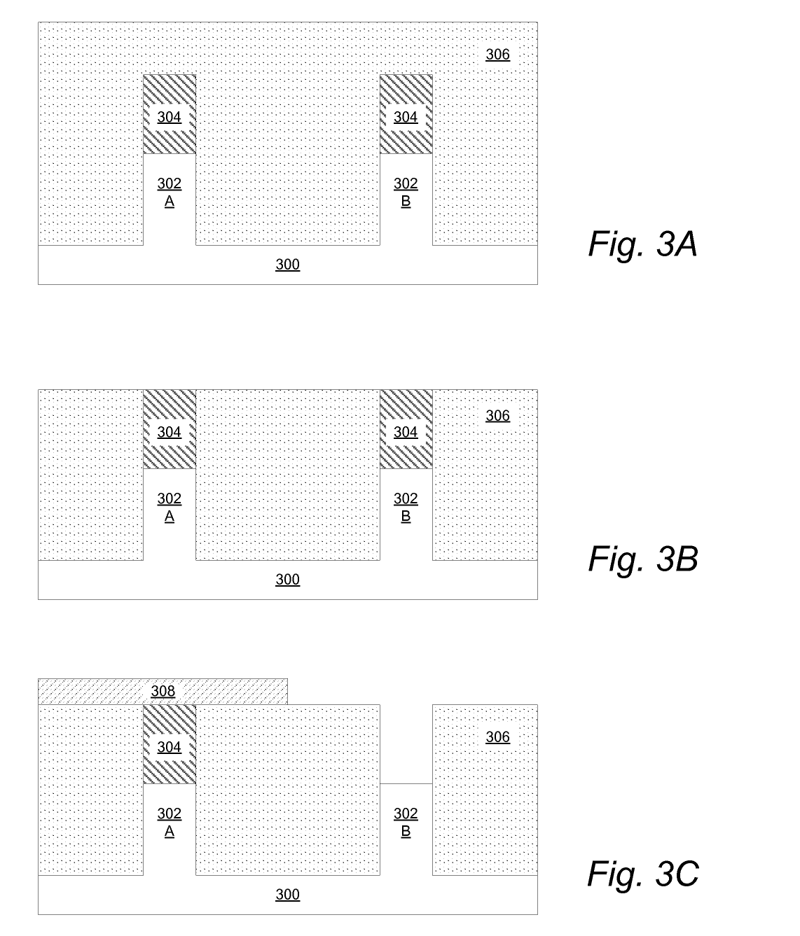

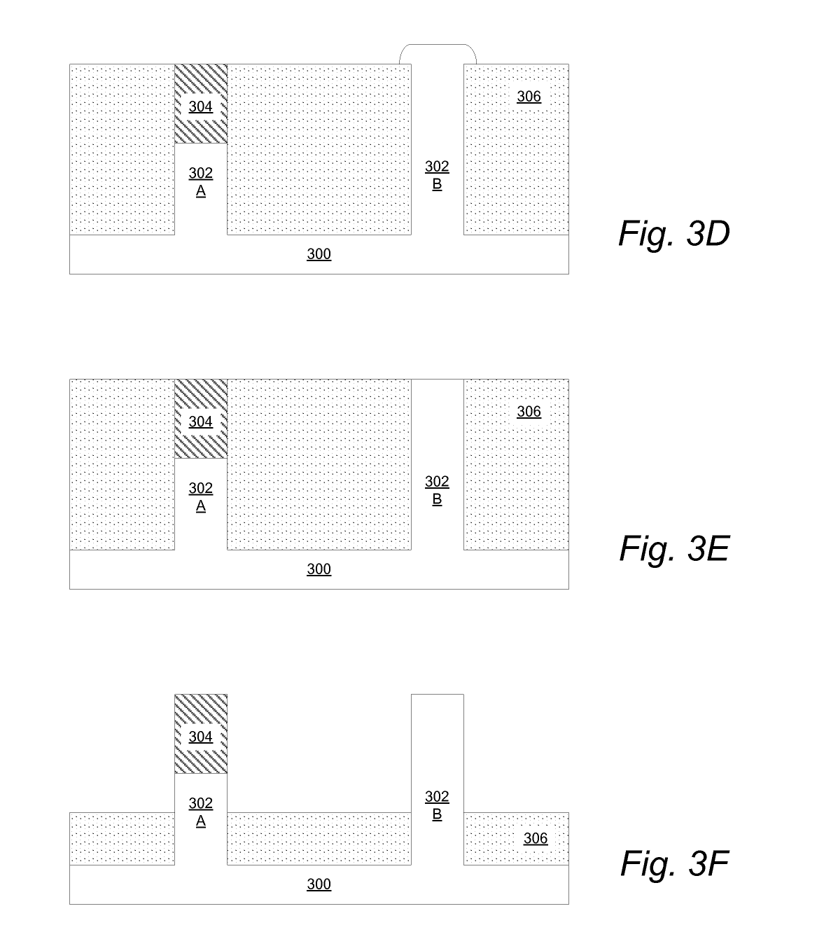

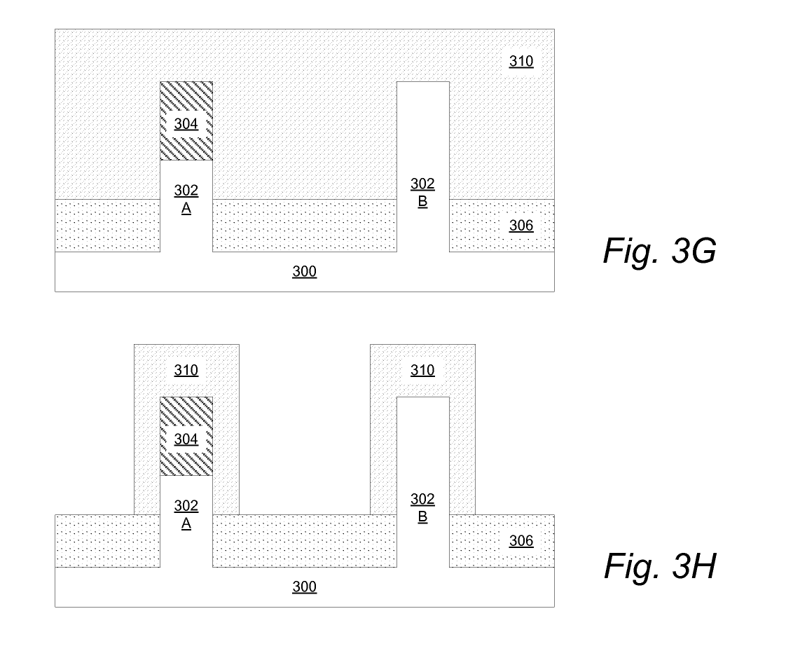

In accordance with an implementation of the invention, FIG. 2 is a method 200 of fabricating a relatively short silicon fin and a relatively long silicon fin on the same substrate without the polysilicon degradation issues discussed above. FIGS. 3A to 3H illustrate structures formed when the method of FIG. 2 is carried out.

The method 200 begins by providing a semiconductor substrate (202). In various implementations of the invention, the semiconductor substrate is a crystalline substrate that may be formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

Two or more silicon fins having substantially the same height are fabricated on the surface of the semiconductor substrate (204). In accordance with an implementation of the invention, one process for fabricating the silicon fins begins by depositing an isolation layer on the substrate. The isolation layer may be formed using a material such as nitride or oxynitride and may have a thickness that falls between around 10 nanometers (nm) and 100 nm. In implementations of the invention, the isolation layer has a thickness that is relatively greater than the thickness of conventional isolation layers used in forming silicon fins. As will be demonstrated below, the thickness of the isolation layer corresponds to the difference in height between the relatively short silicon fin and the relatively long silicon fin.

The isolation layer is then patterned using conventional lithography processes to form isolation structures that function as a mask defining the silicon fins. A silicon etching process follows to etch the substrate through the isolation structures and fabricate the silicon fins. In accordance with implementations of the invention, the isolation structures remain atop the silicon fins after the substrate etching process. In some implementations of the invention, a photoresist material may be used to directly pattern the silicon fins in lieu of the isolation structures.

Although this description refers to the fins as “silicon” fins, those of skill in the art will recognize that the fins are generally formed of the same material as the substrate. The substrate typically consists of bulk silicon, therefore, the fins are typically silicon fins. In alternate implementations, the fins may be formed of a material that differs from the substrate. For example, silicon fins may be epitaxially grown on a substrate formed of a material other than pure silicon. For purposes of this description, even though the fins may be formed of a material other than silicon, the fins will be referred to herein as “silicon fins”.

An insulating layer is deposited over the substrate, including within the trenches between the silicon fins (206). In some implementations, the insulating layer may consist of a material used in conventional shallow trench isolation processes, including but not limited to silicon dioxide. In some implementations, the insulating layer may consist of an interlayer dielectric material, including but not limited to silicon dioxide, carbon doped oxide, silicon nitride, organic polymers such as perfluorocyclobutane, polytetrafluoroethylene, fluorosilicate glass, and organosilicates such as silsesquioxane, siloxane, or organosilicate glass.

FIG. 3A illustrates a substrate 300 having a pair of silicon fins 302 adjacent to one another. As will be demonstrated below, one silicon fin 302A will be used to form the relatively short silicon fin while the other silicon fin 302B will be used to form the relatively long silicon fin. An isolation structure 304 is located on a top surface of each of the silicon fins 302. Again, the thickness of the isolation structure 304 corresponds to the height difference that will be created between the relatively short silicon fin 302A and the relatively long silicon fin 302B to be formed. An insulating layer 306 formed of a material such as silicon dioxide is deposited over the entire structure and fills the trench between the silicon fins 302.

The insulating layer is then etched or planarized down to the top of the isolation structures (208). Conventional processes for planarizing or etching the insulating layer may be used. The end point for the planarization or etching process occurs when the top surfaces of the isolation structures are exposed. FIG. 3B illustrates the insulating layer 306 after it has been polished down to the top surfaces of the isolation structures 304.

Next, a masking layer is deposited on the insulating layer and patterned to form a masking structure over the silicon fin that will be used to form the relatively short silicon fin (210). The masking layer may be formed of silicon nitride or any other conventional masking material. The patterned masking structure does not mask the silicon fin that will be used to form the relatively long silicon fin, thereby leaving its corresponding isolation structure exposed. FIG. 3C illustrates a masking structure 308 that masks the relatively short silicon fin 302A but does not mask the silicon fin 302B that will be used to form the relatively long silicon fin.

With the masking structure in place, the exposed isolation structure is etched away by applying an appropriate wet etch chemistry (212). In some implementations of the invention, a wet or a dry etching process known in the art for removing nitride layers may be used, such as hot phosphoric acid. The etching process continues until the isolation structure is removed and the underlying silicon fin is exposed. In implementations of the invention, the isolation structure is substantially removed or completely removed. FIG. 3C illustrates the removal of the exposed isolation structure 304 from atop the silicon fin 302B, thereby forming a trench over the silicon fin 302B.

An epitaxial deposition process is then carried out to grow silicon in the trench above the exposed silicon fin, thereby extending the silicon fin to form a relative long silicon fin (214). Conventional epitaxial deposition processes may be used to deposit the silicon layer on the exposed silicon fin. For instance, conventional low pressure chemical vapor epitaxial deposition processes based on SiH₄ or dichloro-silane chemistry may be used to deposit the silicon layer on the exposed silicon fin. After the trench is filled, a planarization process follows to remove excess silicon from the surface of the insulating layer (216). Conventional planarization processes known in the art may be used. In some implementations, the planarization process also removes the masking structure. Alternatively, an etching process may be used to remove the excess silicon.

The silicon growth on the exposed silicon fin and the subsequent planarization result in the height of the exposed silicon fin being increased by an amount that is substantially equal to the height of the trench. The height of the trench is, in turn, controlled by the thickness of the initial isolation layer. Therefore, the height of the relatively long silicon fin may be controlled by way of the isolation layer.

FIG. 3D illustrates how the silicon fin 302B has been extended by epitaxially depositing silicon on its top surface. A relatively long silicon fin 302B has now been fabricated that is adjacent to the relatively short silicon fin 302A. As shown, excess silicon tends to become deposited atop the surface of the insulating layer 306. FIG. 3E illustrates the long silicon fin 302B after this excess silicon has been removed using a planarization process.

After formation of the relatively long silicon fin is complete, the insulating layer is recessed (218). The insulating layer is recessed until at least a portion of the relatively short silicon fin is exposed. A portion of the relatively long silicon fin will already be exposed by the time the relatively short silicon fin becomes exposed. Conventional etching processes for the chosen insulating layer may be used, such as a hydrofluoric acid wet etch or a dry oxide etch. In some implementations, the isolation structure on the relatively short silicon fin may now be removed. In other implementations, the isolation structure may remain on the relatively short silicon fin. FIG. 3F illustrates the recessed insulating layer 306. In the implementation shown, the isolation structure 304 remains on the shorter silicon fin 302A.

A gate dielectric layer and a gate electrode layer are then deposited over the short and long silicon fins (220). The gate dielectric layer may be formed using conventional gate dielectric materials, such as a high-k dielectric material. The gate electrode layer may be formed using conventional gate electrode materials, such as polysilicon or a metal typically used for metal gate electrodes. FIG. 3G illustrates a gate electrode layer 310 on the silicon fins 302. The gate dielectric layer is not shown in FIG. 3G for clarity.

Finally, the gate electrode layer and the gate dielectric layer may be etched to form individual gate dielectric layers and gate electrodes for each of the two silicon fins (222). This is illustrated in FIG. 3H. The etching of the gate dielectric layer and the gate electrode layer may occur in subsequent processes after both layers are deposited. Alternately, the gate dielectric layer may be etched before the gate electrode layer is deposited.

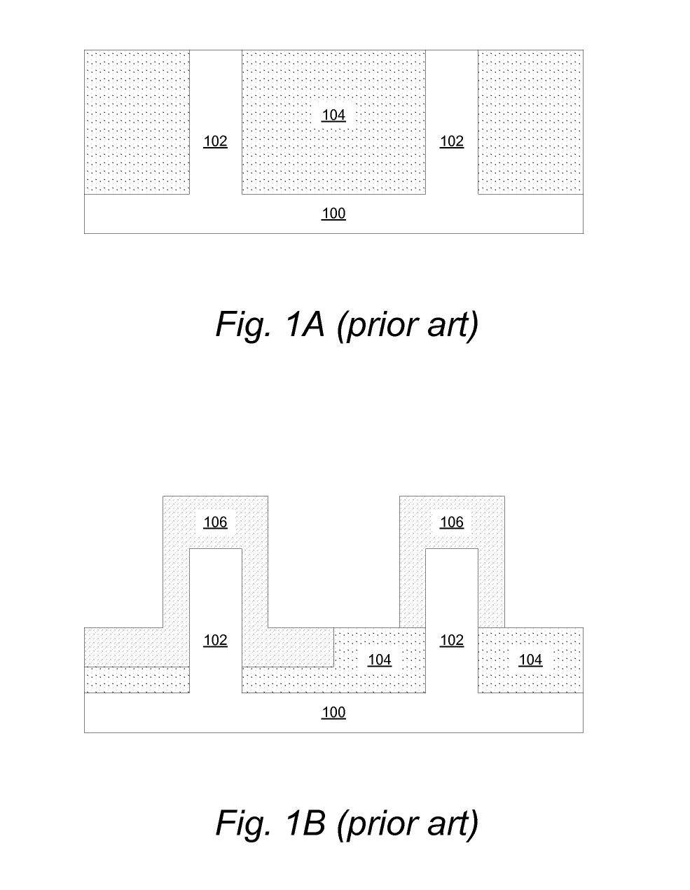

As shown in FIG. 3H, because the recessed insulating layer 306 has a level surface, the etching of the gate electrode layer reaches its end-point at the same time on both silicon fins 302. This is contrary to the prior art process described above and illustrated in FIG. 1 where the polysilicon etching over the short fin reaches its end-point before the polysilicon etching over the long fin is complete. Again, in the prior art process, the polysilicon atop the short fin suffers from over-etching and notching while waiting for the polysilicon etching on the long fin to reach its end-point. In accordance with the implementations described here, because the gate electrode etching ends at the same time on both fins, neither silicon fin suffers from over-etching or notching issues.

In some implementations, the isolation structure on the short fin may be removed at this point in the process. In further implementations, removal of the isolation structure may occur at a later point in the process. In yet further implementations, the isolation structure may remain on the relatively short silicon fin because epitaxial growth widens the silicon fins beneath the isolation structures and contact with the gate electrode can still be made.

As will be recognized by those of skill in the art, the above described process may be modified to fabricate adjacent silicon fins having more than two heights. For instance, silicon fins of an intermediate height may be formed by stopping the epitaxial deposition process before the silicon completely fills the trench. The remainder of the trench may be filled with an isolation structure or a sacrificial layer and the intermediate silicon fin may then be masked while another silicon fin is extended to a greater height.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
fabricating a first and a second silicon fin on a semiconductor substrate, wherein each silicon fin includes an isolation structure on its top surface;
depositing an insulating layer on the semiconductor substrate;
forming a masking structure that masks the first silicon fin but does not mask the second silicon fin;
removing the isolation structure from atop the second silicon fin;
extending the second silicon fin by epitaxially depositing a silicon layer on its top surface; and
removing at least a portion of the insulating layer.

2. The method of claim 1, wherein the isolation structure comprises a material selected from the group consisting of nitride and oxynitride.

3. The method of claim 2, wherein the isolation structure has a thickness that falls between around 10 nm and 100 nm.

4. The method of claim 1, wherein the insulating layer comprises silicon dioxide.

5. The method of claim 1, wherein the masking structure comprises silicon nitride.

6. The method of claim 1, wherein the removing of the isolation structure from atop the second silicon fin comprises applying a wet etch chemistry to remove the isolation structure.

7. The method of claim 1, further comprising removing the masking structure prior to removing at least a portion of the insulating layer.

8. The method of claim 1, further comprising planarizing the epitaxially deposited silicon layer to remove excess silicon.

9. The method of claim 1, further comprising planarizing the insulating layer to expose the top surfaces of the isolation structures before forming the masking structure.

10. A method comprising:
providing a silicon substrate having an isolation layer deposited thereon;
patterning the isolation layer to form a first isolation structure and a second isolation structure;
patterning the silicon substrate to form a first silicon fin beneath the first isolation structure and a second silicon fin beneath the second isolation structure;
depositing an insulating layer on the semiconductor substrate;
planarizing the insulating layer to expose a top surface of the first isolation structure and a top surface of the second isolation structure;
depositing a masking layer on the insulating layer;
patterning the masking layer to form a masking structure that masks the first isolation structure but does not mask the second isolation structure;
applying a wet etch chemistry to remove the second isolation structure and expose the second silicon fin;
epitaxially depositing a silicon layer on the second silicon fin; and
recessing the insulating layer to expose at least a portion of the first silicon fin and at least a portion of the second silicon fin.

11. The method of claim 10, further comprising:
depositing a conformal dielectric layer over the first silicon fin and the second silicon fin;
depositing an electrode layer on the conformal dielectric layer; and
patterning the electrode layer and the dielectric layer to form a first gate dielectric layer and a first gate electrode atop the first silicon fin and a second gate dielectric layer and a second gate electrode atop the second silicon fin.

12. The method of claim 10, further comprising planarizing the epitaxially deposited silicon layer to remove excess silicon.

13. The method of claim 10, wherein the isolation layer comprises a nitride layer or an oxynitride layer.

14. The method of claim 10, wherein the masking layer comprises silicon nitride.

15. The method of claim 11, wherein the conformal dielectric layer comprises a high-k dielectric layer.

16. The method of claim 11, wherein the electrode layer comprises a polysilicon layer or a metal layer.

17. An apparatus comprising:
a silicon substrate;
a first silicon fin formed on the silicon substrate, wherein the first silicon fin has a first height; and
a second silicon fin formed on the silicon substrate, wherein the second silicon fin has a second height that is greater than the first height.

18. The apparatus of claim 17, wherein the difference in height between the first silicon fin and the second silicon fin is produced by epitaxially depositing a silicon layer atop the second silicon fin.

19. The apparatus of claim 17, further comprising a gate dielectric layer and a gate electrode formed on each of the first and second silicon fins.

20. The apparatus of claim 17, wherein the first silicon fin is adjacent to the second silicon fin.
